(19) United States
(12) Patent Application Publication
(10) Pub. No.: US 2025/0338483 A1
(43) Pub. Date: Oct. 30, 2025

(54) SEMICONDUCTOR DEVICE INCLUDING BURIED CHANNEL ARRAY TRANSISTOR

(71) Applicant: SAMSUNG ELECTRONICS CO., LTD., SUWON-SI (KR)

(72) Inventors: KYO-SUK CHAE, Suwon-si (KR); TAIUK RIM, Suwon-si (KR); SUNGJOO WI, Suwon-si (KR); SeungGi Jeom, Suwon-si (KR)

(21) Appl. No.: 19/028,975

(22) Filed: Jan. 17, 2025

(30) Foreign Application Priority Data
Apr. 26, 2024 (KR) 10-2024-0056311

(51) Int. Cl. H10B 12/00

(52) U.S. Cl. CPC H10B 12/34; H10B 12/053

(57) ABSTRACT

A semiconductor device may include a substrate having a gate trench, a gate dielectric layer disposed on an inner surface of the gate trench, a first gate pattern disposed on the gate dielectric layer and defining a lower portion of the gate trench, a second gate pattern disposed on the first gate pattern, at least a portion of the second gate pattern disposed in the lower portion of the gate trench, and a capping insulating pattern disposed on the second gate pattern. The semiconductor device may include a first blocking layer disposed on the first gate pattern and on a sidewall of the second gate pattern, a doped polysilicon layer disposed on the first blocking layer, a second blocking layer disposed on the doped polysilicon layer, and a spacer mask disposed on the second blocking layer.

### CROSS-REFERENCE TO RELATED APPLICATION

This application claims the benefit under 35 U.S.C. § 119 to Korean Patent Application No. 10-2024-0056311, filed on Apr. 26, 2024, in the Korean Intellectual Property Office, the entire disclosure of which is herein incorporated by reference for all purposes.

### BACKGROUND

### 1. Field of the Invention

The present disclosure relates to a semiconductor device including a buried channel array transistor (BCAT).

### 2. Discussion of Related Art

Semiconductor device development is becoming increasingly difficult as margins for process defects decrease, and tradeoffs between device characteristics and reduced size increase.

### SUMMARY

According to an aspect, a semiconductor device may include a substrate including a gate trench, a gate dielectric layer disposed on an inner surface of the gate trench, a first gate pattern disposed on the gate dielectric layer and defining a lower portion of the gate trench, a second gate pattern disposed on the first gate pattern, at least a portion of the second gate pattern disposed in the lower portion of the gate trench, a capping insulating pattern disposed on the second gate pattern, a first blocking layer disposed on the first gate pattern and on a sidewall of the second gate pattern, a doped polysilicon layer disposed on the first blocking layer, a second blocking layer disposed on the doped polysilicon layer, and a spacer mask disposed on the second blocking layer.

According to another aspect, a semiconductor device may include a substrate that includes a plurality of active regions spaced apart from each other and a line-shaped gate trench that crosses the plurality of active regions, a gate dielectric layer disposed inside the gate trench and in contact with the plurality of active regions, a first gate pattern disposed on the gate dielectric layer defining a lower portion of the gate trench, a second gate pattern disposed on the first gate pattern, at least a portion of the second gate pattern disposed in the lower portion of the gate trench, a capping insulating pattern disposed on the second gate pattern, a first blocking layer disposed on the first gate pattern and on a sidewall of the second gate pattern, a doped polysilicon layer disposed on the first blocking layer and on a sidewall of the second gate pattern, a second blocking layer disposed on the doped polysilicon layer, and a spacer mask disposed on the second blocking layer and on a sidewall of the capping insulating pattern.

According to another aspect, a method of manufacturing a semiconductor device may include forming a gate trench in a substrate, forming a gate dielectric layer on an inner surface of the gate trench of the substrate, forming a first gate pattern on the gate dielectric layer, the first gate pattern defining a lower portion of the gate trench, sequentially stacking, in the gate trench, a first blocking layer, a doped polysilicon layer, and a second blocking layer on the first gate pattern, performing a heat treatment process by introducing an oxygen gas, stacking a spacer mask along a surface of the gate dielectric layer disposed on an upper sidewall of the gate trench and a top surface of the second blocking layer, etching a central portion of the gate trench including an upper portion of the first gate pattern in the lower portion of the gate trench such that a central portion of the first gate pattern remains at a first height, forming a second gate pattern having a second height on the central portion of the first gate pattern, and forming a capping insulating pattern having a third height on the second gate pattern.

Additional aspects of embodiments will be set forth in part in the description which follows and, in part, will be apparent from the description, or may be learned by practice of the disclosure.

### BRIEF DESCRIPTION OF THE DRAWINGS

These and/or other aspects, features, and advantages of the invention will become apparent and more readily appreciated from the following description of embodiments, taken in conjunction with the accompanying drawings of which:

FIG. 1 is a plan view illustrating a semiconductor device according to an embodiment;

FIG. 2 is a cross-sectional view illustrating a semiconductor device according to an embodiment, taken along line A-A′ of FIG. 1;

FIG. 3 is a cross-sectional view illustrating a semiconductor device according to an embodiment, taken along line B-B′ of FIG. 1;

FIG. 4 is an enlarged cross-sectional view illustrating a portion X of FIG. 3;

FIG. 5 is a cross-sectional view illustrating components of a semiconductor device according to a comparative example;

FIG. 6A, FIG. 6B, FIG. 6C, FIG. 6D, FIG. 6E, and FIG. 6F are cross-sectional views illustrating a method of manufacturing a semiconductor device according to a process order, according to an embodiment; and

FIG. 7A, FIG. 7B, FIG. 7C, FIG. 7D, and FIG. 7E are cross-sectional views illustrating examples of a semiconductor device according to an embodiment.

### DETAILED DESCRIPTION

Hereinafter, embodiments will be described in detail with reference to the accompanying drawings. When describing embodiments with reference to the accompanying drawings, like reference numerals refer to like components and a repeated description related thereto may be omitted or simplified.

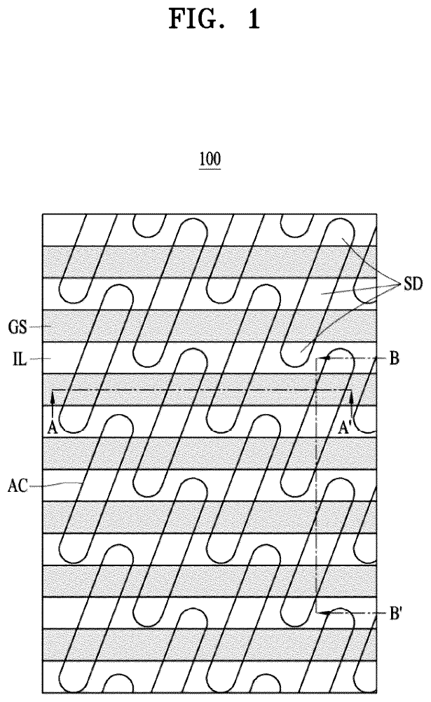

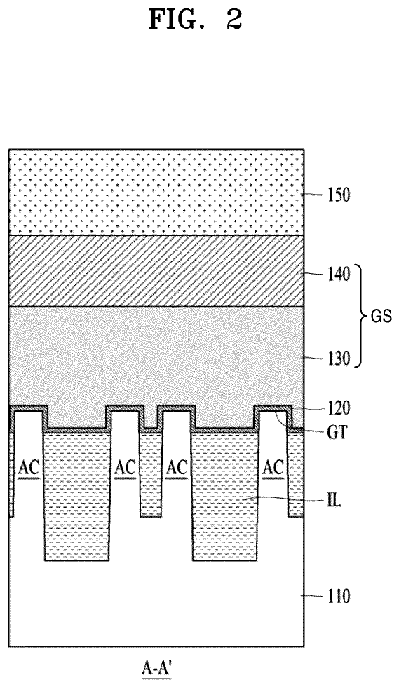

FIG. 1 is a plan view of a semiconductor device according to an embodiment.

Referring to FIG. 1, according to an embodiment, a semiconductor device 100 may include a substrate 110. The substrate 110 may include a device isolation region and an active region. More specifically, on the substrate 110, a plurality of active regions AC may be spaced apart from each other and may define by a device isolation layer IL, and a plurality of gate trenches GT (see FIG. 2) crossing the plurality of active regions AC may be formed. For example, a plurality of gate trenches GT having line-shapes may cross the plurality of active regions AC.

For example, the substrate 110 may include a semiconductor material, such as silicon, germanium, or silicon-germanium, or a Group III-V compound semiconductor, such as GaP, GaAs, or GaSb.

The plurality of active regions AC may be arranged spaced apart from each other in a horizontal direction and a vertical direction in a plan view. The plurality of active regions AC may each be shaped to extend in a direction inclined with respect to the horizontal direction and the vertical direction. The plurality of gate trenches GT may have a shape of a plurality of lines extending parallel to each other in the horizontal direction.

The device isolation layer IL may be formed of a silicon oxide layer or a silicon nitride layer, or a combination thereof.

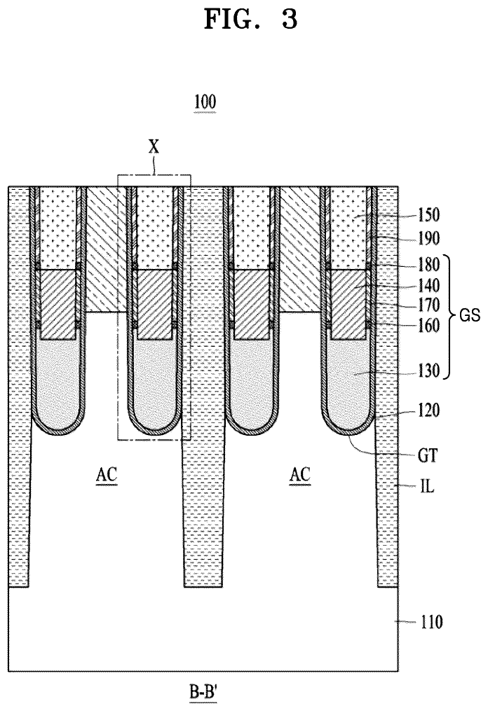

Referring to FIG. 3, a gate dielectric layer 120, a gate structure GS, and a capping insulating pattern 150 may be disposed inside the gate trench GT. The gate structure GS may bury a portion of the gate trench GT on the gate dielectric layer 120. The capping insulating pattern 150 may cover the gate structure GS inside the gate trench GT may be formed.

The gate dielectric layer 120 may be conformally formed along a sidewall and a bottom surface of the gate trench GT. The gate dielectric layer 120 may have a predetermined thickness, for example, a thickness of about 150 angstroms (Å) or less, and more specifically, a thickness of about 30 Å to 100 Å. However, embodiments are not limited thereto. In addition, the gate dielectric layer 120 may include a silicon oxide, a silicon nitride, a silicon oxynitride, or a high dielectric material having a dielectric constant greater than that of a silicon oxide.

FIG. 3 is a cross-sectional view taken along line B-B′ of FIG. 1. Referring to FIG. 3, the gate structure GS may include the first gate pattern 130 and the second gate pattern 140. The first gate pattern 130 may be formed on the gate dielectric layer 120, and the second gate pattern 140 may be formed on the first gate pattern 130. The gate structure GS may further include a first blocking layer 160, a doped polysilicon layer 170, and a second blocking layer 180. The first blocking layer 160 may be disposed above a top surface of a central portion of the first gate pattern 130 and on a sidewall of the second gate pattern 140. For example, the first blocking layer 160 may be disposed on an outer portion of the first gate pattern 130 and between the sidewall of the second gate pattern 140 and the gate dielectric layer 120. The doped polysilicon layer 170 may be disposed on the first blocking layer 160 and on the sidewall of the second gate pattern 140. For example, the doped polysilicon layer 170 may be disposed between the sidewall of the second gate pattern 140 and the gate dielectric layer 120. The second blocking layer 180 may be disposed on the doped polysilicon layer 170. The second blocking layer 180 may be disposed on a sidewall of at least one of the capping insulating pattern 150 or the second gate pattern 140. For example, the second blocking layer 180 may be disposed between the capping insulating pattern 150 and the gate dielectric layer 120.

In addition, a spacer mask 190 may be formed on the second blocking layer 180 and on the sidewall of at least one of the capping insulating pattern 150 or the second gate pattern 140.

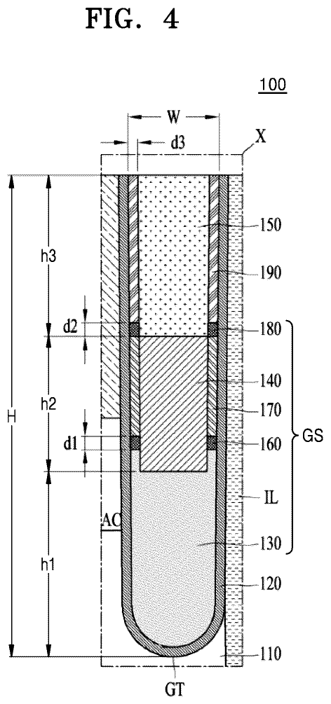

Hereinafter, components of a semiconductor device according to an embodiment are described in detail with reference to FIG. 4. However, components of a semiconductor device (e.g., a semiconductor device 100 of FIG. 4) described herein are merely examples for illustrating the technical idea of the present disclosure, and the scope of the present disclosure is not limited thereto.

FIG. 4 is an enlarged cross-sectional view illustrating a portion X of FIG. 3.

Referring to FIG. 4, according to an embodiment, the semiconductor device 100 may include a substrate 110, a gate dielectric layer 120, a gate structure GS, and a capping insulating pattern 150. The substrate 110 may include a gate trench GT. The gate dielectric layer 120 may be disposed on an inner surface of the gate trench GT. The gate structure GS may be disposed on the gate dielectric layer 120 and configured to bury a portion of the gate trench GT. The capping insulating pattern 150 may be configured to cover the gate structure GS.

The gate structure GS may include a first gate pattern 130 and a second gate pattern 140 disposed on the first gate pattern 130. The first gate pattern 130 may define a lower portion of the gate trench GT, and at least a portion of the second gate pattern 140 may be disposed in the lower portion of the gate trench GT. For example, the lower portion of the gate trench GT may be defined by a top surface of the central portion of the first gate pattern 130, above which the first blocking layer 160 may be disposed.

In addition, the gate structure GS may include the first blocking layer 160, the doped polysilicon layer 170, the second blocking layer 180, and a spacer mask 190. The first blocking layer 160 may be disposed on the outer portion of the first gate pattern 130 above the top surface of the central portion of the first gate pattern 130 and on a sidewall of the second gate pattern 140. The second blocking layer 180 may be disposed on an upper sidewall of the second gate pattern 140, or a lower sidewall of the capping insulating pattern 150 disposed above a top surface of the second gate pattern 140. The doped polysilicon layer 170 may be disposed between the first blocking layer 160 and the second blocking layer 180, and on a sidewall of the second gate pattern 140. The spacer mask 190 may be disposed on the second blocking layer 180 and on the sidewall of the capping insulating pattern 150.

According to an embodiment, the first gate pattern 130 may include a metal, or a metal nitride, or a combination thereof, and may include, for example, TIN, W, WN, or Mo. A characteristic of a material used for the first gate pattern 130 may include a high conductivity, and have thermal stability even at a high temperature, for example, about 1000° C. or greater, in a subsequent process. For example, a material in which a work function has about 4.5 eV corresponding to a mid-gap state of silicon, or that is a p-type material may be suitable.

The first gate pattern 130 may have a first height hl from a surface of the gate trench GT. The first height h1 may be measured from a bottom surface of the gate trench GT.

In addition, a barrier metal pattern may be disposed between the first gate pattern 130 and the gate dielectric layer 120. The barrier metal pattern may be disposed along a top surface of the gate dielectric layer 120, to surround a sidewall and a bottom surface of the first gate pattern 130. As a result, the first gate pattern 130 may be disposed on the barrier metal pattern in the lower portion of the gate trench GT to have the first height h1. For example, the first gate pattern 130 may be formed on the barrier metal pattern and the gate dielectric layer 120 to fill the lower portion of the gate trench GT to have the first height h1.

In addition, the second gate pattern 140 may include a material identical to or different from that of the first gate pattern 130. The, the first gate pattern 130 and the second gate pattern 140 may be formed of a same type of material or different types of materials. For example, a material in which a work function has about 4.5 eV corresponding to a mid-gap state of silicon, or that is a p-type material may be suitable. Further, a work function of the first gate pattern 130 may be greater than or equal to a work function of the second gate pattern 140.

According to an embodiment, the first blocking layer 160 may be disposed above the top surface of the central portion of the first gate pattern 130 and on a lower sidewall of the second gate pattern 140. The first blocking layer 160 may include a metal, such as Titanium (Ti) or Tantalum (Ta), or a nitride, such as Titanium Nitride (TiN), Tungsten Nitride (WN), Aluminum Nitride (AlN), or Silicon Nitride (SiN), however, embodiments are not limited thereto. For example, the first blocking layer 160 may include any material with a high conductivity. In addition, when the first gate pattern 130 and the first blocking layer 160 are formed of the same type of material, the material used for the first blocking layer 160 may be an N-rich material in comparison to a material used for the first gate pattern 130, and a metal nitride formed by nitriding a surface of the first gate pattern 130 may also be used. The first blocking layer 160 may be a layer to inhibit or prevent a reaction of TiN, and the like by oxygen (O₂) when the second blocking layer 180 is subsequently formed and may inhibit or prevent an oxidation. A thickness dl of the first blocking layer 160 may be about 20 Å or less, or about 10 Å or less.

According to an embodiment, the second blocking layer 180 may be disposed on at least one of the upper sidewall of the second gate pattern 140 or the lower sidewall of the capping insulating pattern 150 above the top surface of the second gate pattern 140. The second blocking layer 180 may include a silicon oxide or a silicon nitride, or a combination thereof. The second blocking layer 180 may be used to inhibit or prevent a dopant (e.g., phosphorus (P)) from being outgassed during a heat treatment of the doped polysilicon layer 170. The second blocking layer 180 may include a material that may reduce a diffusivity of phosphorus (P) without a limitation to types of the materials, and may include a material, for example, Silicon Dioxide (SiO₂) or SiN. For example, the second blocking layer 180 may include SiO₂.

The second blocking layer 180 may have a work function less than that of the capping insulating pattern 150. A thickness d2 of the second blocking layer 180 may be less than or equal to 20 Å, which may be similar to or different from the thickness d1 of the first blocking layer 160. Various combinations of the thickness d1 of the first blocking layer 160 and the thickness d2 of the second blocking layer 180 that may perform functions as respective blocking layers may be formed without being significantly limited.

According to an embodiment, the doped polysilicon layer 170 may be disposed between the first blocking layer 160 and the second blocking layer 180, and on the sidewall of the second gate pattern 140 may specifically include polysilicon doped with impurities. For example, the doped polysilicon layer 170 may include polysilicon doped with phosphorus (P).

In a process of manufacturing a semiconductor device according to an embodiment, when a heat treatment is performed by allowing O₂ to flow after a polysilicon etch-back (PEB) step, a phenomenon in which the dopant P in the doped polysilicon layer 170 may migrate toward an interface between a polysilicon layer and a gate dielectric layer may occur. For example, when a heat treatment is performed by allowing O₂ to flow after a polysilicon etch-back (PEB) step, the dopant P may move to the interface between a polysilicon layer and a gate dielectric layer.

For example, when a heat treatment is performed on the polysilicon layer 170 including a dopant (e.g., phosphorus (P)) formed on the first blocking layer 160, the dopant may move along a grain boundary and the dopant may be accumulated in an interface between the polysilicon layer 170 and the gate dielectric layer 120. Given a migrated dopant, a central portion of the doped polysilicon layer 170, stacked on the first blocking layer 160, may be replaced with the second gate pattern 140. In a case where the central portion of the doped polysilicon layer 170, stacked on the first blocking layer 160, is replaced with the second gate pattern 140, a resistance of a word line may be reduced, and a disconnection defect of a buried channel array transistor (BCAT) may be eliminated. For example, an area where a disconnection defect of a BCAT may occur may be reduced or eliminated. Here, a concentration (number/cm³) of phosphorus (P) included in the doped polysilicon layer 170 may be greater than or equal to about 1×10²⁰ atoms/cm³.

In addition, in a case that the central portion of the doped polysilicon layer 170, stacked on the first blocking layer 160, is replaced with the second gate pattern 140, a thickness of the doped polysilicon layer 170, remaining on a sidewall of the gate trench GT, from the gate dielectric layer 120 may be greater than or equal to about 5 Å, and less than half of a width of the gate trench GT. The thickness of the doped polysilicon layer 170 may vary depending on a width of a gate trench GT of a semiconductor device that is formed and may, for example, range from about 10 Å to 100 Å.

According to an embodiment, the spacer mask 190 may be disposed above the second blocking layer 160 and on the sidewall of the capping insulating pattern 150. The spacer mask 190 may include a silicon oxide layer or a silicon nitride layer, or a combination thereof. The same material as that of the second blocking layer 180 may be used for the spacer mask 190. For example, the spacer mask 190 may include, for example, SiO₂. In an embodiment, in a case that the second blocking layer 180 and the spacer mask 190 are formed of a same material, the second blocking layer 180 and the spacer mask 190 may be formed at a same time. In an embodiment, the hard mask may include SiN. In a case that the hard mask includes SiN, a preservation of a hard mask (not shown) formed on the substrate 110 may be improved.

As described herein, the gate trench GT of the semiconductor device according to an embodiment may include the gate dielectric layer 120, the first gate pattern 130, the second gate pattern 140, the capping insulating pattern 150, the first blocking layer 160, the doped polysilicon layer 170, the second blocking layer 180, and the spacer mask 190.

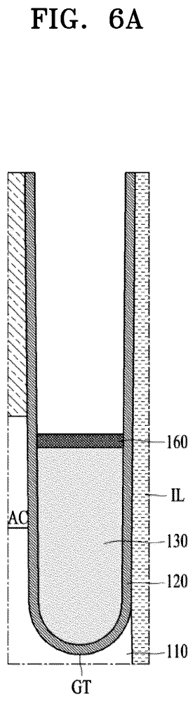

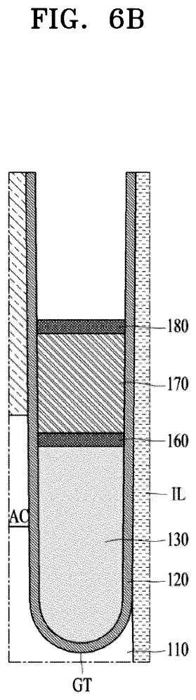

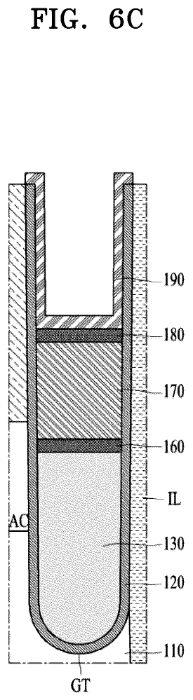

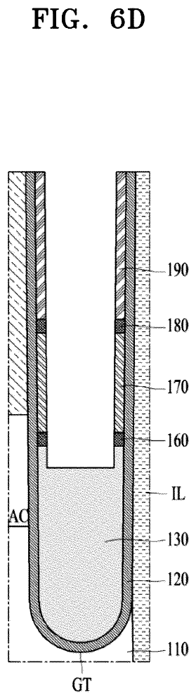

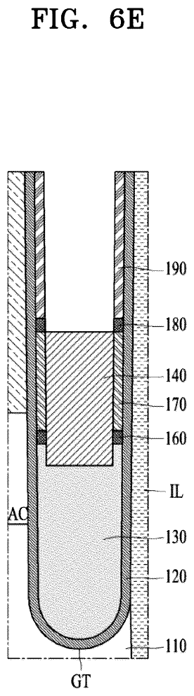

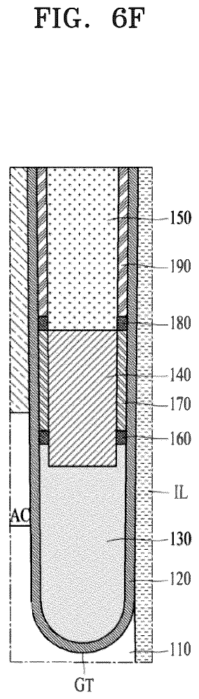

FIG. 6A, FIG. 6B, FIG. 6C, FIG. 6D, FIG. 6E, and FIG. 6F are cross-sectional views illustrated according to a process sequence to describe a method of manufacturing a semiconductor device according to an embodiment.

According to an embodiment, a gate trench GT may be formed on the substrate 110. For example, to form the gate trench GT, a hard mask (not shown) may be formed on the substrate 110, and an upper portion of the substrate 110 may be etched using the hard mask as an etch mask.

In this example, the hard mask may include SiN. However, the material of the hard mask is not limited thereto.

According to an embodiment, a gate dielectric layer 120 may be conformally formed on a surface of the gate trench GT and a top surface of the hard mask. The gate dielectric layer 120 may include a silicon oxide, but is not limited thereto. The gate dielectric layer 120 may be formed by, for example, a thermal oxidation process or an atomic layer deposition process.

The gate dielectric layer 120 may be formed to have a predetermined thickness from the surface of the gate trench GT. For example, the gate dielectric layer 120 may have a predetermined thickness of about 150 Å or less, and more specifically, a thickness of about 30 Å to 100 Å, however, embodiments are not limited thereto.

A first gate pattern 130 may be formed on the gate dielectric layer 120. The first gate pattern 130 may include a metal or a metal nitride, or a combination thereof. For example, the first gate pattern 130 may include Ti, TiN, Ta, TaN, W, WN, or molybdenum (Mo). In another example, the first gate pattern 130 may include a material, such as TiN, W, WN, or Mo. For example, the first gate pattern 130 may include TiN. A characteristic of a material included in the first gate pattern 130 may include a thermal stability at a high temperature, for example, about 1000° C. or greater.

At least a portion of the first gate pattern 130 disposed in an upper portion of the gate trench GT may be removed. The portion of the first gate pattern 130 disposed in the upper portion of the gate trench GT may be removed by an etch-back process. In the etch-back process, the gate dielectric layer 120 formed on an inner sidewall of the gate trench GT may be maintained. For example, the gate dielectric layer 120 may not be etched.

As described herein, the first gate pattern 130 having a predetermined height from a bottom surface of the gate trench GT may be formed.

Referring to FIG. 6A, a first blocking layer 160 may be disposed on the first gate pattern 130 that buries a lower portion of the gate trench GT.

The first blocking layer 160 may be formed by a plasma process or a deposition process. The first blocking layer 160 may include a metal, such as Ti or Ta, or at least one nitride among TiN, WN, AlN, or SiN, or may include a metal nitride formed by nitriding a top surface of the central portion of the first gate pattern 130. For example, the first blocking layer 160 may include TiN. In other words, the first blocking layer 160 may include an N-rich metal nitride layer having an amount of nitrogen greater than an amount of nitrogen included in a metal of the first gate pattern 130. In addition, the thickness d1 of the first blocking layer 160 may be about 20 Å or less, or may be about 10 Å or less.

The first blocking layer 160 may inhibit or prevent an oxidation by blocking a reaction of first blocking layer 160 with O₂ when a second blocking layer is subsequently formed. The first blocking layer 160 may contribute to maintaining the properties and electrical characteristics of the first gate pattern 130 buried in the lower portion of the gate trench GT.

Referring to FIG. 6B, a doped polysilicon layer 170 may be disposed on the first blocking layer 160.

The doped polysilicon layer 170 may include polysilicon doped with impurities. For example, the doped polysilicon layer 170 may include polysilicon doped with phosphorus (P).

A second blocking layer 180 may be disposed on the polysilicon layer 170.

The second blocking layer 180 may be formed by a plasma process or a deposition process. The second blocking layer 180 may inhibit or prevent a dopant (e.g., phosphorus (P)) from being outgassed during a heat treatment of the doped polysilicon layer 170 and may inhibit or prevent electrical characteristics of layers disposed therebelow from changing or being physically or chemically damaged.

Materials that may reduce the diffusivity of the phosphorus (P) may be used as the second blocking layer 180 without a limitation to types thereof. For example, the second blocking layer 180 may include a silicon oxide or a silicon nitride, or a combination thereof. For example, the second blocking layer 180 may include a material, such as SiO₂ or SiN. For example, the second blocking layer 180 may include SiO₂.

The thickness d2 of the second blocking layer 180 may be less than or equal to about 20 Å, similar to or different from the thickness d1 of the first blocking layer 160.

Based on a method described herein, the gate dielectric layer 120, the first gate pattern 130, the first blocking layer 160, the doped polysilicon layer 170, and the second blocking layer 180 may be sequentially stacked in the gate trench GT, oxygen (O₂) gas may be introduced, and a heat treatment may be performed.

In general, after a first gate pattern and a doped polysilicon layer are stacked, a heat treatment may be performed after etch-back of the first gate pattern and the doped poly-silicon film to remove impurities included in a gate. Here, a dopant (e.g., phosphorus (P)) of the doped polysilicon layer may be outgassed, which may cause a reduction in a gate induced drain leakage (GIDL) electric field (E-field) improvement effect due to a low work function. According to an embodiment, by performing a heat treatment process after polysilicon etch-back, SiO₂ may be formed on the doped polysilicon layer 170, which may inhibit or prevent an outgassing of a dopant. Here, a phenomenon in which phosphorus (P) migrates along a grain boundary to be accumulated in an interface between the polysilicon layer 170 and the gate dielectric layer 120 may occur. Through a dopant migration phenomenon, a central portion of the doped polysilicon layer 170 may be etched and replaced with the second gate pattern 140, wherein the second gate pattern 140 may be disposed deep inside a trench. Thus, a resistance of a word line may be reduced, an area wherein a disconnection defect of a BCAT may occur may be reduced, and GIDL E-field and row hammer effects may also be reduced. In addition, the heat treatment process may be performed at a high temperature, for example, at about 800° C. or greater, or at about 1000° C. or greater.

Referring to FIG. 6C, a spacer mask 190 may be disposed on the second blocking layer 180. The spacer mask 190 may be stacked along a surface of the gate dielectric layer 120 disposed on an upper sidewall of the gate trench GT and a top surface of the second blocking layer 180. The spacer mask 190 may include a silicon oxide layer or a silicon nitride layer, or a combination thereof. The spacer mask 190 may be formed of the same material as a material of the second blocking layer 180, and may include, for example, SiO₂. When the spacer mask 190 includes SiO₂, a subsequent etching process may be facilitated. The hard mask (not shown) formed on the substrate 110 may include SiN. For example, at least a portion of the hard mask including SiN may be preserved during the etching process.

Referring to FIG. 6D, in a stack structure disposed in the gate trench GT, a central portion of the gate trench GT may be etched from an upper portion of the gate trench GT and at least an upper portion of the lower portion of the gate trench GT defined by the first gate pattern 130. The central portion of the gate trench GT may be defined by a width and a depth extending downward from an upper surface of the semiconductor device. The width of the central portion of the gate trench GT may be less than the width W defined by the gate dielectric layer 120 (see FIG. 4). For example, an upper portion of the first gate pattern 130 may be etched, and the first gate pattern 130 may remain at a first height h1 in the central portion of the stack structure. Similarly, the central portion of the gate trench GT may be defined by a thickness (a distance d3 from the gate dielectric layer 120 on the sidewall of the gate trench GT) of the first blocking layer 160, the doped polysilicon layer 170, the second blocking layer 180, and the spacer mask 190 remaining on the sidewall of the gate trench GT after etching. For example, the thickness may be greater than or equal to 5 Å, or less than half of a width of the gate trench GT. Specifically, the thickness may vary depending on a width of a gate trench GT of a semiconductor device that is formed, and may range from about 10 Å to 100 Å.

In addition, the first height h1 of the first gate pattern formed through an etching process may be set such that a top surface of the central portion of the first gate pattern 130 in the central portion of the gate trench GT may be disposed below a bottom surface of the first blocking layer 160 remaining on the sidewall of the gate trench GT. For example, an over-etching may be performed up to a part of an upper portion of the stacked first gate pattern 130 along with the first blocking layer 160. When the over-etching is not performed and when the top surface of the first gate pattern 130 is set to be on the same plane as or a plane similar to the bottom surface of the first blocking layer 160, the first gate pattern 130 may have irregular contact with the second gate pattern 140 that may be formed on the first gate pattern 130, for example, where residual portions of the first blocking layer 160 may remain on the first gate pattern 130 following the etching.

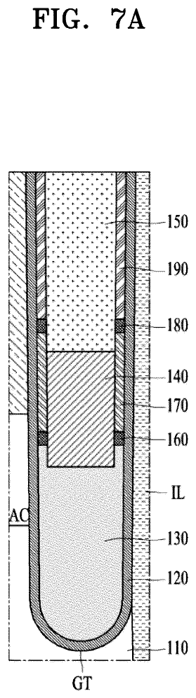

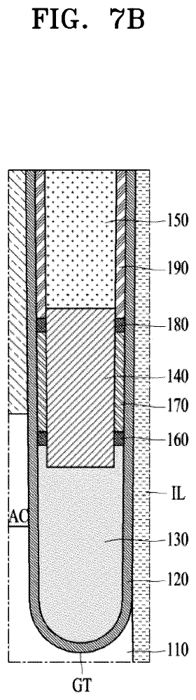

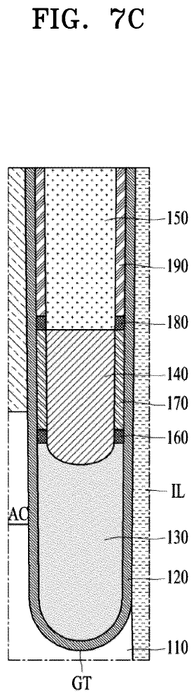

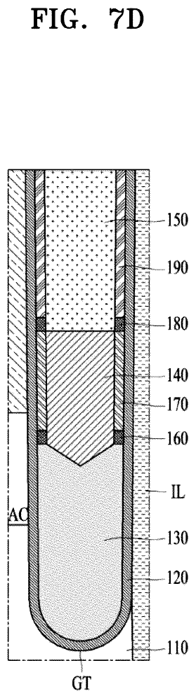

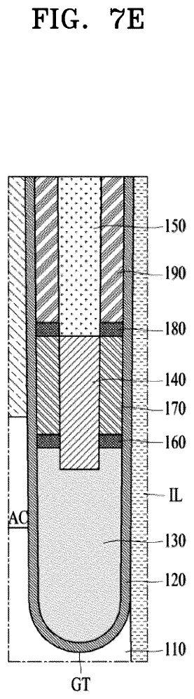

When the first gate pattern 130 is in smooth contact with the second gate pattern 140, an area or a shape of a portion in which the first gate pattern 130 and the second gate pattern 140 contact is not significantly limited. For example, as illustrated in FIG. 7C and FIG. 7D, a contact surface between the first gate pattern 130 and the second gate pattern 140 may have a rounded shape, a sharp shape, or an angled square shape. However, shapes of the contact surface are not limited thereto. For example, the contact surface between the first gate pattern 130 and the second gate pattern 140 may be formed into various shapes using an etching process. In addition, as illustrated in FIG. 7E, due to a change in the thickness of the first blocking layer 160 or the doped polysilicon layer 170, remaining on the sidewall of the gate trench GT, from the gate dielectric layer 120, a contact area between the first gate pattern 130 and the second gate pattern 140 may be controlled. For example, different contact areas may be associated with the different shapes of the contact surface.

Referring to FIG. 6E and FIG. 4, a second gate pattern 140 having a second height h2 may be disposed on the first gate pattern 130. The second gate pattern 140 may be disposed on the central portion of the gate trench GT exposed by the etching. A portion in which the second gate pattern 140 is formed may be regarded to correspond to a central portion of the doped polysilicon layer 170. As described in detail herein, by replacing the central portion of the doped polysilicon layer 170 with the second gate pattern 140, the second gate pattern 140 may be disposed deep inside the gate trench GT. For example, the second gate pattern 140 may extend below the first blocking layer 160. In addition, the second gate pattern 140 may be formed such that a top surface of the second gate pattern 140 and a top surface of the doped polysilicon layer 170 may be on the same plane. The top surface of the second gate pattern 140 may be disposed below the top surface of the doped polysilicon layer 170, as illustrated in FIG. 7A, or may be disposed above the top surface of the doped polysilicon layer 170, as illustrated in FIG. 7B. The height h2 of the second gate pattern 140 may be configured and/or formed to a certain height, such that the second gate pattern 140 does not contact other terminals.

Referring to FIG. 6F, a capping insulating pattern 150 having a third height h3 may be disposed on the second gate pattern 140. The height h3 of the capping insulating pattern 150 is not significantly limited if the capping insulating pattern 150 completely fills an inside of the gate trench GT. For example, by filling the inside of the gate trench GT with the capping insulating pattern 150, the same height as that of a source/drain (SD) may be formed. A material that may form the capping insulating pattern 150 may include, for example, SiN.

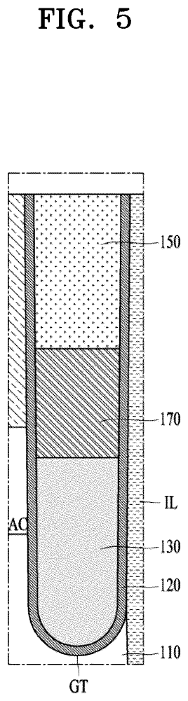

According to an embodiment, GIDL and row hammer effects may be improved in a semiconductor device in which a first blocking layer and a second blocking layer are formed, and in which a heat treatment process is performed by introducing O₂. For example, in a semiconductor device according to a comparative example illustrated in FIG. 5, an area of possible disconnection may be relatively large. In a semiconductor device according to an embodiment, the presence of BCAT disconnection defects may be decreased.

It should be appreciated that various embodiments of the disclosure and the terms used therein are not intended to limit the technological features set forth herein and may include various changes, equivalents, or replacements. With regard to the description of the drawings, similar reference numerals may be used to refer to similar or related components. It is to be understood that a singular form of a noun corresponding to an item may include one or more of the things, unless the relevant context clearly indicates otherwise. As used herein, “A or B,” “at least one of A and B,” “at least one of A or B,” “A, B or C,” “at least one of A, B, and C,” and “at least one of A, B, or C,” may include any one of the items listed together in the corresponding one of the phrases, or all possible combinations thereof. Terms such as “1st” and “2nd,” or “first” and “second” may be used to simply distinguish a corresponding component from other components, and do not limit the components in other aspects (e.g., importance or order).

Unless otherwise defined, all terms including technical and scientific terms used herein have the same meaning as commonly understood by one of ordinary skill in the art to which the embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

When describing embodiments with reference to the accompanying drawings, like reference numerals refer to like components and a repeated description related thereto may be omitted or simplified. In the description of embodiments, detailed description of well-known related structures or functions may be omitted or simplified when such description may cause ambiguous interpretation of the present disclosure.

In addition, terms such as first, second, A, B, (a), (b), and the like may be used to describe components of the embodiments. These terms are used only for the purpose of discriminating one component from another component, and the nature, the sequences, or the orders of the components are not limited by the terms. When one component is described as being “connected,” “coupled,” or “attached” to another component, it should be understood that one component may be connected or attached directly to another component, and an intervening component may also be “connected,” “coupled,” or “attached” to the components.

A component, which has the same common function as a component included in any one embodiment, will be described by using the same name in other embodiments. Unless disclosed to the contrary, the configuration disclosed in any one embodiment may be applied to other embodiments, and the specific description of the repeated configuration may be omitted or simplified.

The effects to be achieved are not limited to those described herein, and other effects not mentioned herein will be clearly understood by one of ordinary skill in the art from this document.

What is claimed is:

1. A semiconductor device comprising:
a substrate comprising a gate trench;
a gate dielectric layer disposed on an inner surface of the gate trench;
a first gate pattern disposed on the gate dielectric layer and defining a lower portion of the gate trench;
a second gate pattern disposed on the first gate pattern, at least a portion of the second gate pattern disposed in the lower portion of the gate trench;
a capping insulating pattern disposed on the second gate pattern;
a first blocking layer disposed on the first gate pattern and on a sidewall of the second gate pattern;
a doped polysilicon layer disposed on the first blocking layer;
a second blocking layer disposed on the doped polysilicon layer; and
a spacer mask disposed on the second blocking layer.

2. The semiconductor device of claim 1, wherein the first gate pattern and the second gate pattern comprise at least one of a metal or a metal nitride.

3. The semiconductor device of claim 1, wherein a work function of the first gate pattern is greater than or equal to a work function of the second gate pattern.

4. The semiconductor device of claim 1, wherein the first blocking layer comprises at least one of Ti, Ta, TiN, WN, AlN, or SiN.

5. The semiconductor device of claim 1, wherein the second blocking layer comprises at least one of a silicon oxide or a silicon nitride.

6. The semiconductor device of claim 1, wherein the doped polysilicon layer comprises polysilicon doped with phosphorus (P).

7. The semiconductor device of claim 6, wherein a concentration of phosphorus (P) included in the doped polysilicon layer is greater than or equal to about 1×10²⁰ atoms/cm³.

8. The semiconductor device of claim 1, wherein the doped polysilicon layer is disposed on the first blocking layer and on the sidewall of the second gate pattern, and
the spacer mask is disposed on the second blocking layer and on a sidewall of the capping insulating pattern.

9. The semiconductor device of claim 1, wherein a thickness of the doped polysilicon layer in contact with the gate dielectric layer is greater than or equal to about 5 angstroms (Å) and less than half of a width of the gate trench.

10. A semiconductor device comprising:
a substrate comprising a plurality of active regions spaced apart from each other, and a line-shaped gate trench that crosses the plurality of active regions;
a gate dielectric layer disposed inside the gate trench and in contact with the plurality of active regions;
a first gate pattern disposed on the gate dielectric layer defining a lower portion of the gate trench;
a second gate pattern disposed on the first gate pattern, at least a portion of the second gate pattern disposed in the lower portion of the gate trench;
a capping insulating pattern disposed on the second gate pattern;
a first blocking layer disposed on the first gate pattern and on a sidewall of the second gate pattern;
a doped polysilicon layer disposed on the first blocking layer and on a sidewall of the second gate pattern;
a second blocking layer disposed on the doped polysilicon layer; and
a spacer mask disposed on the second blocking layer and on a sidewall of the capping insulating pattern.

11. The semiconductor device of claim 10, further comprising a hard mask disposed on the substrate and comprising a silicon nitride layer.

12. The semiconductor device of claim 10, wherein the spacer mask comprises at least one of a silicon oxide layer or a silicon nitride layer.

13. The semiconductor device of claim 10, wherein the first blocking layer comprises an N-rich metal nitride layer having an amount of nitrogen greater than an amount of nitrogen included in a metal of the first gate pattern.

14. The semiconductor device of claim 10, wherein the second blocking layer comprises a silicon oxide.

15. A method of manufacturing a semiconductor device, the method comprising:
forming a gate trench in a substrate;
forming a gate dielectric layer on an inner surface of the gate trench of the substrate;
forming a first gate pattern on the gate dielectric layer, the first gate pattern defining a lower portion of the gate trench;
sequentially stacking, in the gate trench, a first blocking layer, a doped polysilicon layer, and a second blocking layer on the first gate pattern;
performing a heat treatment process by introducing an oxygen gas;
stacking a spacer mask along a surface of the gate dielectric layer disposed on an upper sidewall of the gate trench and a top surface of the second blocking layer;
etching a central portion of the gate trench including an upper portion of the first gate pattern in the lower portion of the gate trench such that a central portion of the first gate pattern remains at a first height;
forming a second gate pattern having a second height on the central portion of the first gate pattern; and
forming a capping insulating pattern having a third height on the second gate pattern.

16. The method of claim 15, wherein the etching comprises over-etching the central portion of the gate trench such that a top surface of the central portion of the first gate pattern at the first height is below a bottom surface of the first blocking layer.

17. The method of claim 15, wherein a thickness of the doped polysilicon layer, remaining on a sidewall of the gate trench after the etching of the central portion of the gate trench, from the gate dielectric layer is greater than or equal to about 5 angstroms (Å) and less than half a width of the gate trench.

18. The method of claim 15, wherein impurities in a metal of the first gate pattern are removed by the heat treatment process.

19. The method of claim 15, wherein a work function of the second gate pattern has a mid-gap work function of silicon or a work function of a p-type metal.

20. The method of claim 15, wherein
the first gate pattern and the second gate pattern are formed of a material comprising TiN,
the first blocking layer is formed of a material comprising N-rich TiN having an amount of nitrogen greater than an amount of nitrogen included in a metal of the first gate pattern,
the second blocking layer is formed of a material comprising SiO₂, and
the spacer mask is formed of a material comprising SiN or SiO₂.
